(19) United States
(12) Patent Application Publication
(10) Pub. No.: US 2011/0248405 A1
(43) Pub. Date: Oct. 13, 2011

(54) Selective Patterning for Low Cost through Vias

(75) Inventors: Yiming Li, San Diego, CA (US); Mario Francisco Velez, San Diego, CA (US); Shiqun Gu, San Diego, CA (US)

(73) Assignee: QUALCOMM INCORPORATED, San Diego, CA (US)

(21) Appl. No.: 12/757,570

(22) Filed: Apr. 9, 2010

(51) Int. Cl. H01L 23/48; H01L 21/768

(52) U.S. Cl. 257/773; 438/667; 257/E21.597; 257/E23.011

(57) ABSTRACT

A block layer deposited on a substrate before deposition of metal lines and etching of a through via enables low cost fabrication of through vias in a substrate using isotropic etching processes. For example, wet etching of a glass substrate may be used to fabricate through glass vias without undercut from the wet etching shorting metal lines on the glass substrate. The block layer prevents contact between a conductive layer lining the through via with more than one metal line on the substrate. The manufacturing process allows stacking of devices on substrates such as glass substrates and connecting the devices with through vias.

### TECHNICAL FIELD

The present disclosure generally relates to integrated circuits. More specifically, the present disclosure relates to manufacturing integrated circuits.

### BACKGROUND

Silicon substrates used in semiconductor devices have a high cost compared to other materials. For example, building passive devices on a glass substrate would result in lower cost components. Devices stacked on substrates, such as glass substrates, make use of through vias for communicating with other components. One potential application for glass substrates and through vias is liquid crystal displays. Through vias are manufactured in substrates using anisotropic or isotropic etching.

Anisotropic etches occur at different rates along different directions and result in substantially straight sidewalls through the substrate. Anisotropic etches include plasma etching, laser drilling, and mechanical drilling. Anisotropic etches are slow processes that decrease the throughput of manufacturing processes. Isotropic etching etch materials substantially equal in each direction of the substrate. Isotropic etches include wet etching and gas etching. Isotropic etches are lower cost and higher throughput than anisotropic etches, but the undercut resulting from etching in all directions can result in shorting of metal lines on the substrate. A conventional process for manufacturing through vias using isotropic etching is illustrated in FIGS. 1A-C.

Referring to FIG. 1A, metal lines 104 are deposited on a glass substrate 102. Isotropic etching creates a through via 106 in the glass substrate 102 shown in FIG. 1B. Undercutting of the through via 106 by isotropic etching exposes multiple metal lines 104. Referring to FIG. 1C, a through via metal 108 is deposited inside the through via 106. The through via metal 108 contacts multiple metal lines 104 resulting in shorting of the metal lines 104 and failure of the manufactured device.

Thus, there is a need for a process of manufacturing through vias in substrates using isotropic etching without shorting metal lines on the substrate.

### BRIEF SUMMARY

According to one aspect of the disclosure, a method of manufacturing a through via includes patterning a block layer on a first side of a substrate. The method also includes exposing an opening in the block layer. The method further includes depositing a first conductive material on the block layer. The method also includes fabricating the through via on a second side of the substrate opposite the first side. The method further includes depositing a second conductive material in the through via to contact the first conductive material through the opening.

According to another aspect of the disclosure, an integrated circuit includes a substrate. The integrated circuit also includes a block layer having an opening on a first side of the substrate. The integrated circuit further includes a through via on a second side of the substrate extending through the substrate. The integrated circuit also includes a first conductive layer on the block layer extending into the opening. The integrated circuit further includes a second conductive layer on the through via coupling with the first conductive layer through the opening in the block layer.

According to yet another aspect of the disclosure, a method of manufacturing an integrated circuit includes the step of patterning a block layer on a first side of a substrate to form an opening. The method also includes the step of depositing a first conductive material on the block layer. The method further includes the step of fabricating the through via on a second side of the substrate facing opposite the first side. The method also includes the step of depositing a second conductive material in the through via to contact the first conductive material through the opening.

According to a further aspect of the disclosure, an integrated circuit includes a substrate. The integrated circuit also includes means for preventing shorting of metal lines having an opening on a first side of the substrate. The integrated circuit further includes a through via on a second side of the substrate extending through the substrate. The integrated circuit also includes a first conductive layer on the preventing means extending into the opening. The integrated circuit further includes a second conductive layer on the through via coupling with the first conductive layer.

The foregoing has outlined rather broadly the features and technical advantages of the present disclosure in order that the detailed description that follows may be better understood. Additional features and advantages will be described hereinafter which form the subject of the claims of the disclosure. It should be appreciated by those skilled in the art that the conception and specific embodiments disclosed may be readily utilized as a basis for modifying or designing other structures for carrying out the same purposes of the present disclosure. It should also be realized by those skilled in the art that such equivalent constructions do not depart from the technology of the disclosure as set forth in the appended claims. The novel features which are believed to be characteristic of the disclosure, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIGS. 1A-C are cross-sectional views illustrating conventional manufacturing of through vias in a substrate.

FIG. 2 is a flow chart illustrating an exemplary manufacturing process for through vias according to one embodiment.

FIGS. 3A-E are cross-sectional views illustrating an exemplary manufacturing process for through vias according to one embodiment.

FIG. 4 is a block diagram showing an exemplary wireless communication system in which an embodiment of the disclosure may be advantageously employed.

FIG. 5 is a block diagram illustrating a design workstation used for circuit, layout, and logic design of a semiconductor component according to one embodiment.

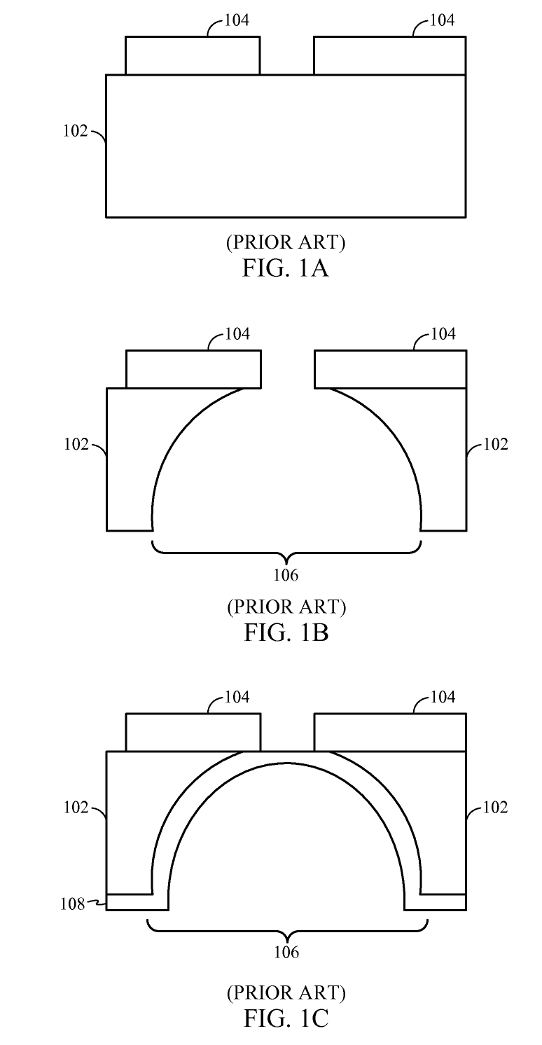

### DETAILED DESCRIPTION

An exemplary process for manufacturing through vias in substrates using isotropic etching is presented. Shorting of metal lines on the substrate after isotropic etching is prevented by patterning a block layer on the substrate before deposition of metal lines on the substrate. The patterned block layer inhibits the opening formed for the through via from exposing more than a single metal line. As a result, each through via contacts only a single metal line. The exemplary process for manufacturing through vias improves reliability of the manufactured devices and increases the yield of manufacturing processes. The exemplary process also decreases the cost of manufactured devices through the use isotropic etches and low cost substrate materials such as glass.

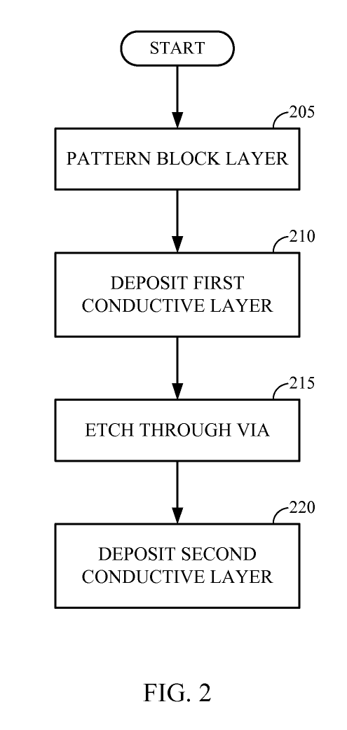

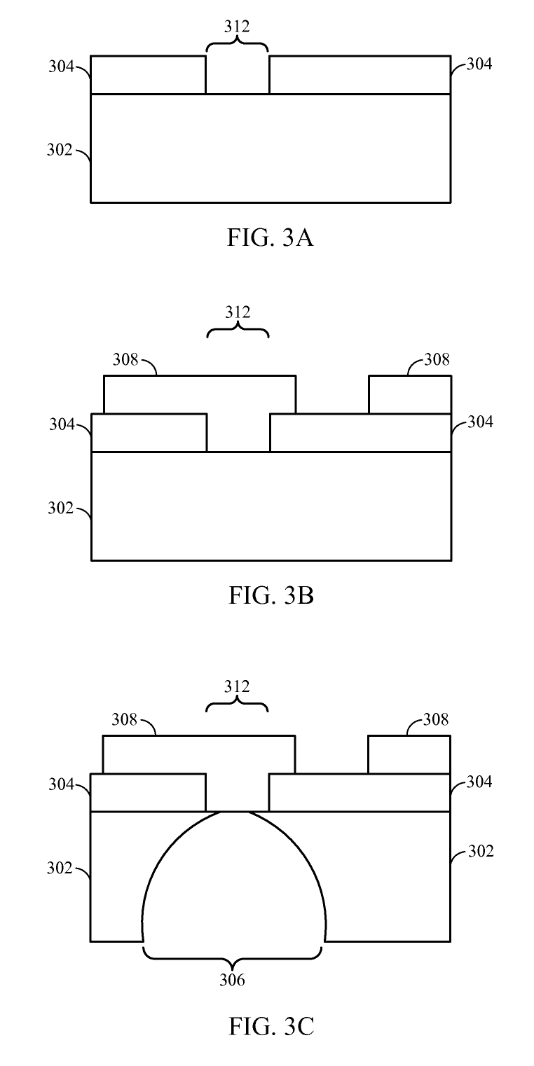

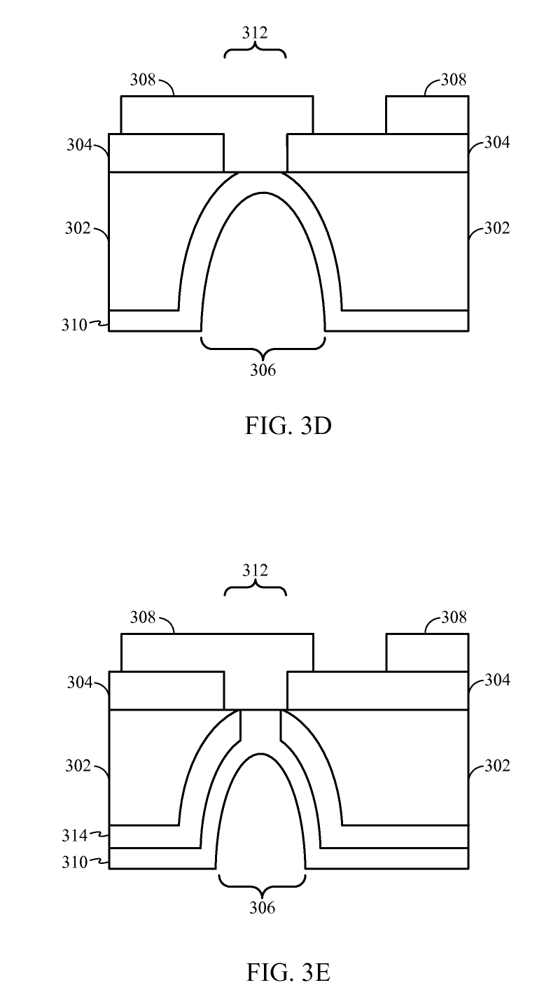

FIG. 2 is a flow chart illustrating an exemplary manufacturing process for through vias according to one embodiment. The exemplary process begins at block 205 with patterning a block layer. FIG. 3A is a cross-sectional view illustrating a substrate after patterning of a block layer according to one embodiment. A block layer 304 is patterned on a substrate 302. The block layer 304 may be, for example, silicon nitride or silicon carbide. An opening 312 patterned in the block layer 304 may correspond to a through via later formed in the substrate 302. According to one embodiment, the opening 312 is not pattered through to the substrate 302. In this embodiment, a portion of the block layer 304 remains in the opening 312 until a later process removes the remaining block layer 304.

The exemplary process continues to block 210 in which a first conductive layer is deposited. FIG. 3B is a cross-sectional view illustrating a substrate after deposition of a first conductive layer according to one embodiment. A first conductive layer 308 is deposited on the block layer 304. The first conductive layer 308 fills the opening 312 and contacts the substrate 302. The first conductive layer 308 may be patterned into metal lines. The first conductive layer 308 may be, for example, copper, aluminum, or tungsten. According to one embodiment, the first conductive layer 308 is 0.02-10 micrometers thick and the block layer 304 is 0.02-5 micrometers thick.

After depositing the first conductive layer 308, the exemplary process etches a through via at block 215. FIG. 3C is a cross-sectional view illustrating a substrate after etching of a through via according to one embodiment. A through via 306 is etched in the substrate 302. According to one embodiment, the substrate 302 is a glass substrate and the through via 306 is a through glass via (TGV). However, the substrate 302 may be other materials such as, for example, silicon or sapphire. The through via 306 may be etched with isotropic etching resulting in undercut of the through via 306 as illustrated in FIG. 3C. According to one embodiment, the location of the through via 306 corresponds to the opening 312 in the block layer 304.

The exemplary process continues to block 220 and deposits a second conductive layer. FIG. 3D is a cross-sectional view illustrating a substrate after depositing the second conductive layer according to one embodiment. A second conductive layer 310 is deposited on a side of the substrate 302 opposite the block layer 304. The second conductive layer 310 lines the inside of the through via 306. According to one embodiment, the second conductive layer 310 contacts one metal line of the first conductive layer 308 through the opening 312 in the block layer 304. In this embodiment, shorting of the metal lines of the first conductive layer 308 is prevented regardless of undercut of the through via 306. The second conductive layer 310 may be, for example, the same material as or different material than the first conductive layer 308.

In another embodiment of the exemplary process illustrated in FIG. 2, an isolation layer may be deposited after etching the through via 306 and before depositing the second conductive layer 310. FIG. 3E is a cross-sectional view illustrating a substrate having a through via with an isolation layer and a second conductive layer according to one embodiment. An isolation layer 314 may be deposited in the through via 306 before deposition of the second conductive layer 310. In this embodiment, the isolation layer 314 is patterned to expose the first conductive layer 308 to the second conductive layer 310. The isolation layer 314 isolates the second conductive layer 310 from the substrate 302. According to one embodiment, the isolation layer 314 prevents shorting of the second conductive layer 310 to the substrate 302. According to another embodiment, the isolation layer 314 improves adhesion of the second conductive layer 310 to the substrate 302. The isolation layer 314 may be, for example, silicon nitride, silicon oxide, or silicon carbide.

The exemplary process for forming through vias in substrates with a block layer described above allows the formation of through vias using isotropic etching processes without significantly reducing reliability of the manufactured devices and without significantly reducing yield of the manufacturing processes. The block layer patterned during the exemplary process inhibits shorting between metal lines on the substrate. According to one embodiment of the exemplary process, through glass vias are manufactured in glass substrates using low cost isotropic etching. Substrates with through vias manufactured according to the process described above may be integrated into integrated circuits (ICs). The through vias may be used to couple devices stacked on the substrate. For example, passive devices such as capacitors and inductors, and MEMS devices such as RF filters may be formed on the glass substrate and coupled to the through vias. According to one embodiment, the glass substrate is stacked on a laminate package substrate. According to another embodiment, the glass substrate is connected to the printed circuit board.

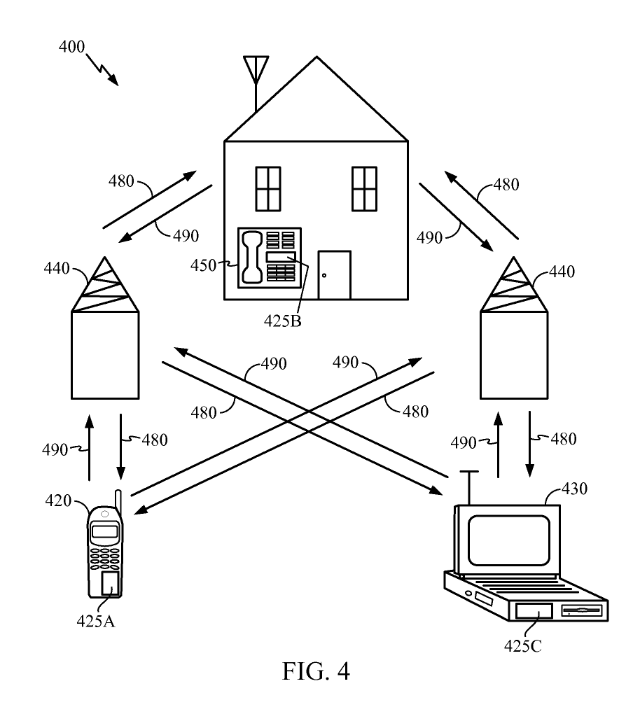

FIG. 4 shows an exemplary wireless communication system 400 in which an embodiment of the disclosure may be advantageously employed. For purposes of illustration, FIG. 4 shows three remote units 420, 430, and 450 and two base stations 440. It will be recognized that wireless communication systems may have many more remote units and base stations. Remote units 420, 430, and 450 include through vias in ICs 425A, 425C, and 425B, respectively, which are embodiments as discussed above. FIG. 4 shows forward link signals 480 from the base stations 440 and the remote units 420, 430, and 450 and reverse link signals 490 from the remote units 420, 430, and 450 to base stations 440.

In FIG. 4, the remote unit 420 is shown as a mobile telephone, the remote unit 430 is shown as a portable computer, and the remote unit 450 is shown as a computer in a wireless local loop system. For example, the remote units may be cell phones, hand-held personal communication systems (PCS) units, portable data units such as personal data assistants, fixed location data units such as meter reading equipment, set top boxes, music players, video players, entertainment units, navigation devices, or computers. Although FIG. 4 illustrates remote units according to the teachings of the disclosure, the disclosure is not limited to these exemplary illustrated units. The disclosure may be suitably employed in any device which includes ICs manufactured with through vias.

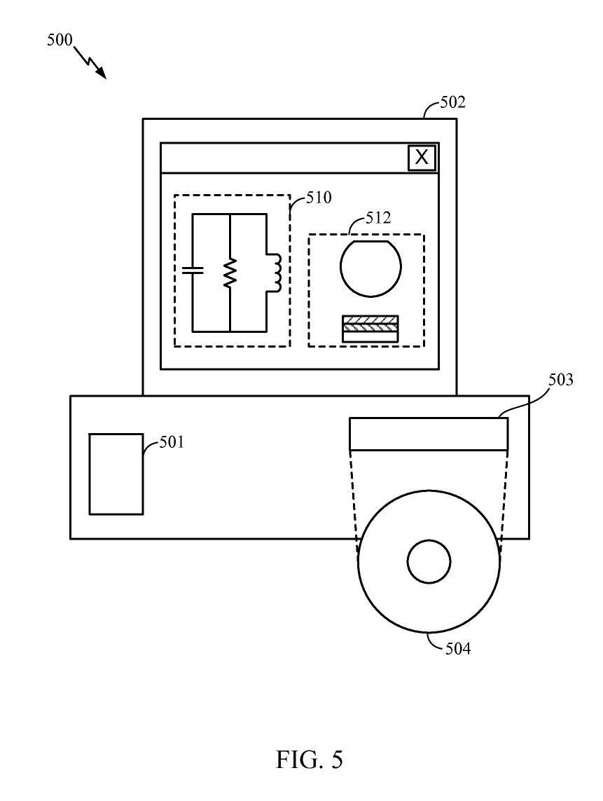

FIG. 5 is a block diagram illustrating a design workstation used for circuit, layout, and logic design of a die or a circuit implemented on a die as disclosed below. A design workstation 500 includes a hard disk 501 containing operating system software, support files, and design software such as Cadence or OrCAD. The design workstation 500 also includes a display to facilitate design of a circuit 510 or a component 512 such as a wafer or die. A storage medium 504 is provided for tangibly storing the circuit design 510 or the component 512. The circuit design 510 or the component 512 may be stored on the storage medium 504 in a file format such as GDSII or GERBER. The storage medium 504 may be a CD-ROM, DVD, hard disk, flash memory, or other appropriate device. Furthermore, the design workstation 500 includes a drive apparatus 503 for accepting input from or writing output to the storage medium 504.

Data recorded on the storage medium 504 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 504 facilitates the design of the circuit design 510 or the component 512 by decreasing the number of processes for designing integrated circuits.

The methodologies described herein may be implemented by various components depending upon the application. For example, these methodologies may be implemented in hardware, firmware, software, or any combination thereof. For a hardware implementation, the processing units may be implemented within one or more application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, electronic devices, other electronic units designed to perform the functions described herein, or a combination thereof.

For a firmware and/or software implementation, the methodologies may be implemented with modules (e.g., procedures, functions, and so on) that perform the functions described herein. Any machine-readable medium tangibly embodying instructions may be used in implementing the methodologies described herein. For example, software codes may be stored in a memory and executed by a processor unit. Memory may be implemented within the processor unit or external to the processor unit. As used herein the term “memory” refers to any type of long term, short term, volatile, nonvolatile, or other memory and is not to be limited to any particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be any available medium that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to store desired program code in the form of instructions or data structures and that can be accessed by a computer; disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions and alterations can be made herein without departing from the technology of the disclosure as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A method of manufacturing a through via, the method comprising:
patterning a block layer on a first side of a substrate;
exposing an opening in the block layer;
depositing a first conductive material on the block layer;
fabricating the through via on a second side of the substrate opposite the first side; and
depositing a second conductive material in the through via to contact the first conductive material through the opening.

2. The method of claim 1, further comprising depositing an isolation material in the through via before depositing the second conductive material.

3. The method of claim 1, in which patterning the block layer comprises patterning the opening to correspond to a location of the through via.

4. The method of claim 1, in which fabricating the through via comprises wet etching the substrate to form the through via.

5. The method of claim 1, in which patterning the block layer comprises patterning at least one of silicon nitride and silicon carbide.

6. The method of claim 1, in which fabricating the through via comprises fabricating a through glass via.

7. The method of claim 1, further comprising integrating the through via into an integrated circuit.

8. The method of claim 7, further comprising integrating the integrated circuit into at least one of a mobile phone, a set top box, a music player, a video player, an entertainment unit, a navigation device, a computer, a hand-held personal communication systems (PCS) unit, a portable data unit, and a fixed location data unit.

9. An integrated circuit, comprising:
a substrate;
a block layer having an opening on a first side of the substrate;
a through via on a second side of the substrate extending through the substrate;
a first conductive layer on the block layer extending into the opening; and
a second conductive layer on the through via coupling with the first conductive layer through the opening in the block layer.

10. The integrated circuit of claim 9, in which a location of the through via corresponds to the opening in the block layer.

11. The integrated circuit of claim 9, in which the block layer is at least one of silicon nitride and silicon carbide.

12. The integrated circuit of claim 9, in which the substrate is glass.

13. The integrated circuit of claim 9, in which the integrated circuit is incorporated into at least one of a mobile phone, a set top box, a music player, a video player, an entertainment unit, a navigation device, a computer, a hand-held personal communication systems (PCS) unit, a portable data unit, and a fixed location data unit.

14. A method of manufacturing an integrated circuit, the method comprising the steps of:
patterning a block layer on a first side of a substrate to form an opening;
depositing a first conductive material on the block layer;
fabricating the through via on a second side of the substrate facing opposite the first side;
depositing a second conductive material in the through via to contact the first conductive material through the opening.

15. The method of claim 14, further comprising the step of depositing an isolation layer in the through via before depositing the second conductive material.

16. The method of claim 14, in which the step of patterning the block layer comprises pattering the opening to correspond to a locations of the through via.

17. The method of claim 14, in which the step of patterning the block layer comprises patterning at least one of silicon nitride and silicon carbide.

18. The method of claim 14, further comprising integrating the integrated circuit into at least one of a mobile phone, a set top box, a music player, a video player, an entertainment unit, a navigation device, a computer, a hand-held personal communication systems (PCS) unit, a portable data unit, and a fixed location data unit.

19. An integrated circuit, comprising:
a substrate;
means for preventing shorting of metal lines having an opening on a first side of the substrate;
a through via on a second side of the substrate extending through the substrate;
a first conductive layer on the preventing means extending into the opening; and
a second conductive layer on the through via coupling with the first conductive layer.

20. The integrated circuit of claim 19, in which the integrated circuit is incorporated into at least one of a mobile phone, a set top box, a music player, a video player, an entertainment unit, a navigation device, a computer, a hand-held personal communication systems (PCS) unit, a portable data unit, and a fixed location data unit.
